(19) United States
(12) Patent Application Publication
(10) Pub. No.: US 2008/0106294 A1
(43) Pub. Date: May 8, 2008

(54) Apparatus and method for universal connectivity in test applications

(75) Inventor: Stephen William Smith, San Jose, CA (US)

Correspondence Address: STEPHEN WILLIAM SMITH, 2302 LAVA DRIVE, SAN JOSE, CA, 95133, US

(73) Assignee: STEPHEN WILLIAM SMITH, SAN JOSE, CA (US)

(21) Appl. No.: 11/591,399

(22) Filed: Nov. 2, 2006

(51) Int. Cl. G01R 31/02

(52) U.S. Cl. 324/763

(57) ABSTRACT

A method and apparatus for using a Universal Test interface in test and measurement applications containing a base unit with at least one electrical, optical, or electromagnetic connection, between this and a parallel interposer with at least one electrical, optical, or electromagnetic connection, a precision alignment and fast attach/release mechanism, and an optional electromagnetic shield.

### CROSS-REFERENCE TO RELATED INVENTIONS

I claim the benefit of the following provisional patents:

Appl No. 60/725,157:—Low Cost patchpanel for Automatic Test Applications.

### FIELD OF THE INVENTION

The field of the invention relates to automatic test equipment), both automatic and manual, more specifically to the testing of components, devices or modules where accuracy, cost or size of the equipment(s) is critical to lowering the cost of test and giving the best possible yield.

### BACKGROUND

Electronic devices are often tested using automatic test equipment(s) (ATE). Generally, the tester includes a computer system that coordinates and runs the tests, and a testing apparatus. The testing apparatus usually includes a test head, into which the device under test (DUT) is placed, a base unit or server which houses power supplies, cooling, control circuitry and any instrumentation that is too bulky to fit into the test-head. Unfortunately each manufacturer of test apparatus has a different testhead size, shape and footprint for electrical connections. Worse each manufacturer has a variety of different testhead sizes, shapes, and footprint for electrical connections. The prior art solution for this has been that each test equipment(s) manufacturers has attempted to overcome this problem by offering so called adaptor or Chameleon boards to convert a Device Under Test (DUT) board designed to run on a competitors tester to work on their tester. But all this does is perpetuate a variety of different clumsy interface standards and now a variety of Chameleon boards too. The situation for rack and stack equipment(s) is even worse because here typically there is a variety of test equipment(s) in a rack with a vast array of cables connecting them to the Device Under Test (DUT) board. Therefore it is extremely difficult and time-consuming to disconnect the Device Under Test (DUT) board from this equipment(s) either for maintenance or testing a different device. Therefore the prior art solution is to have a set of dedicated rack and stack equipment(s) for each Device Under Test (DUT) board making testing by this method costly, space-consuming and inflexible.

The purpose of this invention is to overcome all of the problems stated in a flexible universal test interface which is easy to maintain and creates a universal standard for the test and measurement industry.

### SUMMARY AND OBJECTS OF THE INVENTION

This Invention contains a method for providing a flexible universal interface between Device Under Test (DUT) board and various Automatic Test equipment(s) (ATE) systems.

This Invention contains a method for providing a flexible universal interface between Device Under Test (DUT) board and various rack and stack systems.

This Invention contains a method for providing a flexible universal interface between Device Under Test (DUT) board and various test equipment(s) (automatic or manual).

This Invention contains an apparatus for providing a flexible universal interface between Device Under Test (DUT) board and various Automatic Test equipment(s) (ATE) systems.

This Invention contains an apparatus for providing a flexible universal interface between Device Under Test (DUT) board and various rack and stack systems.

This Invention contains an apparatus for providing a flexible universal interface between Device Under Test (DUT) board and various test equipment(s)) (automatic or manual).

between the test board/module and the device under test. (DUT).

### BRIEF DESCRIPTION OF DRAWINGS

FIG. 1 Illustrates one embodiment of the Universal Connectivity Apparatus using a modular Inter poser.

FIG. 2 Illustrates one embodiment of Universal Connectivity Apparatus using a custom Interposer.

FIG. 3 Illustrates a perspective drawing of one embodiment of the base unit.

FIG. 4 Illustrates a perspective drawing of one embodiment of the custom interposer unit.

FIG. 5 Illustrates a perspective drawing of one embodiment of the modular interposer unit.

FIG. 6 Illustrates a perspective drawing of one embodiment of custom interposer with base unit

FIG. 7 Illustrates a perspective drawing of one embodiment of modular interposer with base unit

FIG. 8 Illustrates one embodiment of the custom interconnect with base unit pogo pin module.

FIG. 9 Illustrates one embodiment of modular interconnect with pogo pin modules.

FIG. 10 Illustrates one embodiment of the custom Interconnect with blind-mate high frequency coaxial base unit module.

FIG. 11 Illustrates one embodiment of the modular interconnect using blind-mate high frequency coaxial modules.

FIG. 12 Illustrates one embodiment of the Universal Connectivity Apparatus with custom Inter poser and third-party tester.

FIG. 13 Illustrates one embodiment of the Universal Connectivity Apparatus with modular Inter poser and third-party tester.

FIG. 14 Illustrates one embodiment of the Universal Connectivity Apparatus with custom Inter poser and third-party test equipment(s).

FIG. 15 Illustrates one embodiment of the Universal Connectivity Apparatus with modular Inter poser and third-party test equipment(s).

FIG. 16 Illustrates one embodiment of the Universal Connectivity Apparatus with custom Inter poser and built-in test instrumentation.

FIG. 17 Illustrates one embodiment of the Universal Connectivity Apparatus with modular Inter poser and built-in test instrumentation.

FIG. 18 Illustrates one embodiment of the custom interconnect with optical modules.

FIG. 19 Illustrates one embodiment of the modular interconnect solution with optical modules.

FIG. 20 Illustrates one embodiment of the custom interconnect with electromagnetic modules.

FIG. 21 Illustrates one embodiment of modular interconnect using electromagnetic modules.

### DETAILED DESCRIPTION

A method and apparatus for using a Universal Test interface in test and measurement applications is described. Using a Universal Test Interface for test applications allows rapid changing of device of modules being tested without the need for rewiring, it also provides a standard interface which eliminates the need for different type of loadboard for each test system used, it also provides a modular construction making it very easy to replace damaged connectors, or to reconfigure the unit to meet different test requirements. Further the integral test module version of this solution enables a very short connection path between the test modules and device or module under test thus eliminating cables and giving optimum signal fidelity.

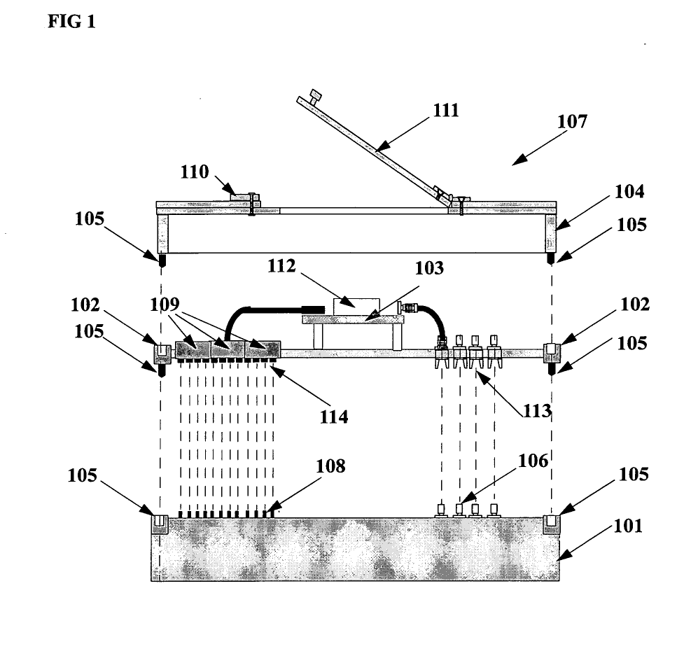

FIG. 1 illustrates one embodiment of the Universal Connectivity Apparatus using modular interposer. The main pieces of this embodiment consists of the modular base unit 101, the modular interposer unit 102, the Device Under Test Board 103, and optionally the Radio Frequency (RF) shield unit 104. The modular base unit 101 provides a test interface between the system described herein and the test equipment(s) or modules used for make a measurements forming the test base station. The Device Under Test Board 103 is then attached and electrically connected to the modular interposer unit 102, this then forms a test assembly. The test module can then be easily attached and detached from the base station making it possible to use the same base station for different test assemblies. In this embodiment the base unit 101 has coaxial Radio Frequency (RF) connectors 106 for Radio Frequency (RF), microwave, high speed, or low noise signals, it also has pogo pins which would usually be used for digital, control, power, or lower speed Radio Frequency (RF) connections. Additionally the base unit 101 has a locating mechanism 105 which is used to accurately align the interposer unit 102 to avoid damaging or causing excessive wear to the connectors. The interposer unit 102 comprises it's corresponding part of locating mechanism 105, Radio Frequency (RF) connector modules 113, and pogo pin contact/connector modules 114. Pogo connector modules 114 make connection with base unit pogo pin modules 108, and Radio Frequency (RF) connector modules 114 make connection with base unit Radio Frequency (RF) connector modules 106.

Connections are then taken as required from the pogo pin contact/connector modules 114 to the Device Under Test Board 103. Likewise Radio Frequency (RF) coaxial connections may be taken from the Radio Frequency (RF) connector modules 114 to the Device Under Test Board 103. Each Device or module under test may then fitted to the Device Under Test Board 103. Further an optional Radio Frequency (RF) shield unit 104 may be employed which fits onto the interposer board 102. The optional Radio Frequency (RF) shield 104 would generally have a lid 111 which makes it possible to easily replace the device or module under test without the need to remove the entire shield. The lid in this instance is hinged and locked in place by a retaining clip 110. However for faster testing this lid could equally be of a sliding arrangement, or when docked with a prober handler may be replaced by the shielding provided by the prober handler itself.

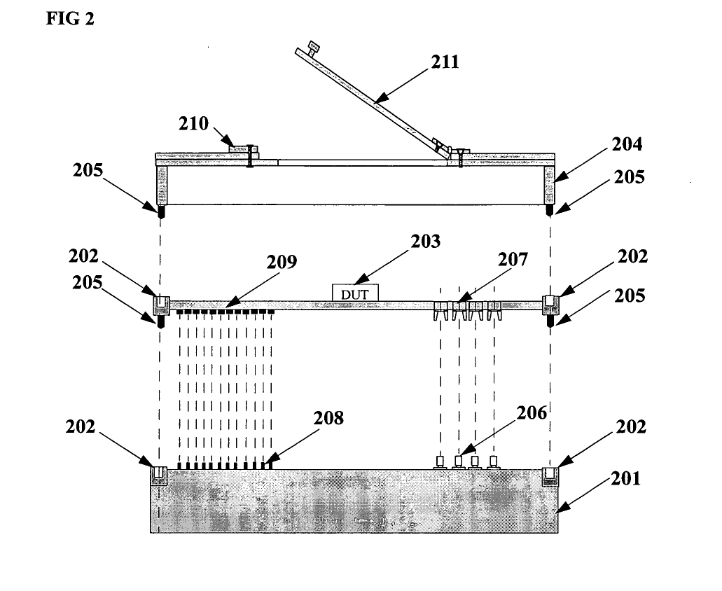

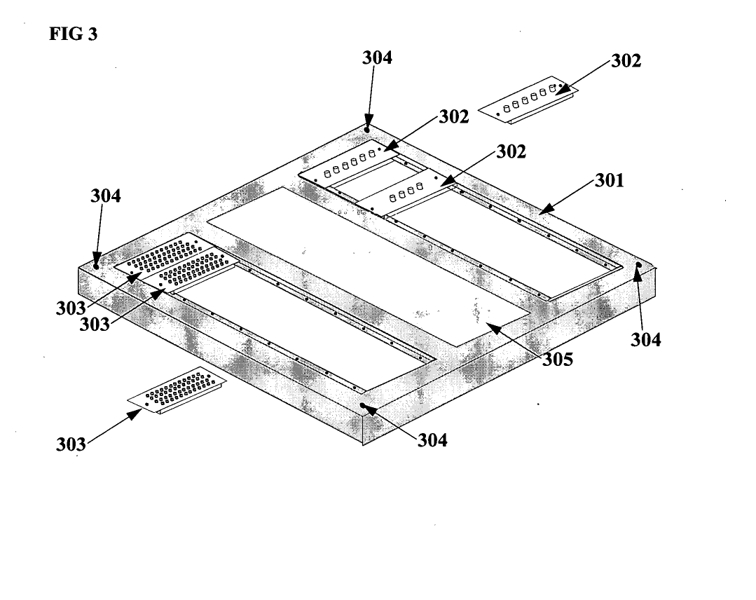

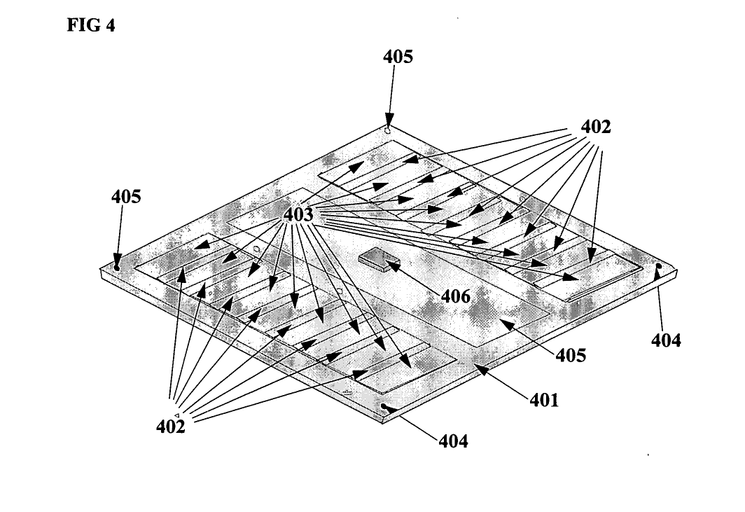

FIG. 2 illustrates another embodiment of the Universal Connectivity Apparatus using modular interposer. The main pieces of this embodiment consists of the modular base unit 201, the custom interposer unit 202, the device under test site 203 and optionally the Radio Frequency (RF) shield unit 204. The modular base unit 201 provides a test interface between the system described herein and the test equipment(s) or modules used for make a measurements forming the test base station. The Device Under Test socket 103 is electrically connected to and an integral part of the custom interposer unit 102, this then forms a test assembly. The test assembly can then be easily attached and detached from the base station making it possible to use the same base station for different test assemblies. In this embodiment the base unit 201 has coaxial Radio Frequency (RF) connectors 106 for Radio Frequency (RF), microwave, high speed, or low noise signals, it also has pogo pins which would usually be used for digital, control, power, or lower speed Radio Frequency (RF) connections. Additionally the base unit 201 has a locating mechanism 205 which is used to accurately align the interposer unit 202 to avoid damaging or causing excessive wear to the connectors. The interposer unit 202 comprises it's corresponding part of locating mechanism 205, the integral Radio Frequency (RF) connectors 213, and integral pogo pin contacts 214. The integral pogo contacts 214 make connection with base unit pogo pin modules 208, and the integral Radio Frequency (RF) connectors 214 make connection with base unit Radio Frequency (RF) connector modules 106. The required electrical connections between the interposer unit 202 and the Device Under Test socket 203 for Radio Frequency (RF), pogo pin contacts or any other form of interconnect is defined during custom design process as required. Further the optional Radio Frequency (RF) shield unit 204 may be employed which fits onto the custom interposer board 202. The optional Radio Frequency (RF) shield 204 would generally have a lid 211 which makes it possible to easily replace the device or module under test without the need to remove the entire shield. The lid in this instance is hinged and locked in place by a retaining clip 210. However for faster testing this lid could equally be of a sliding arrangement, or when docked with a prober handler may be replaced by the shielding provided by the prober handler itself. FIG. 3 illustrates one embodiment of the Universal connectivity solution base unit. The Base unit comprises the base assembly 301 which has a number of modular connector slots. The different connector types are then housed in the various slots, either to a predetermined pattern or configured to suit specific user requirements. In this embodiment two types of module are shown, namely the pogo pin module 303 which provides a high density mass interconnect, and the Radio Frequency (RF) Coaxial interconnect module which provides a very wide band-width impedance controlled environment. The base unit also has a number of locating mechanisms 304 which as mentioned earlier ensure precision alignment to the interposer when docking. FIG. 4 illustrates one embodiment of the Universal connectivity solution custom interposer unit. The custom interposer unit comprises the frame assembly 401 which houses and provides alignment and mechanical support for the custom circuit board 405. In this embodiment the frame assembly is conductive around its perimeter and also would be used to house optional conductive EMI shielding for when used with the optional Radio Frequency (RF) shield. The different connector types are then positioned on the circuit board layout to mate with the corresponding base unit slots. Again this can either be a predetermined pattern or configured to suit specific user requirements.

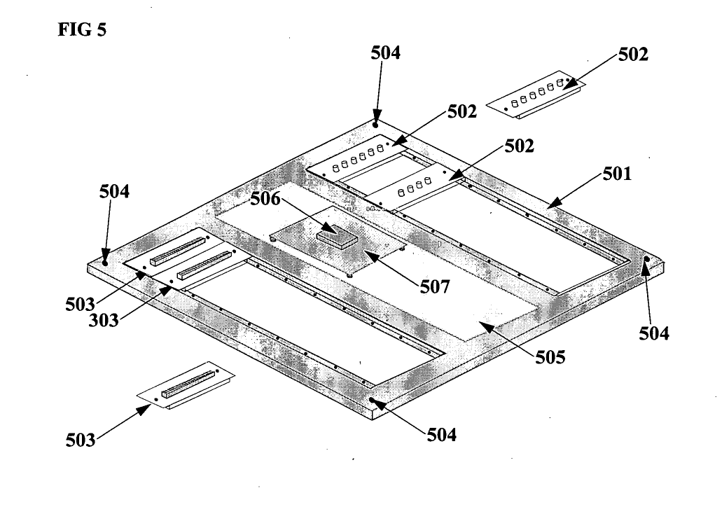

The types and positioning of the connector or contacts are then designed to mate with the corresponding connector or contacts for that slot position on the base unit, with precision alignment provided to the base unit via precision alignment mechanism(s) 404. Further the precision alignment mechanism(s) 404 may also be used for aligning an optional Radio Frequency (RF) shield. FIG. 5 illustrates one embodiment of the Universal connectivity solution custom interposer unit. The modular interposer unit comprises the frame assembly 501 which houses and provides alignment, mounting slots, and mechanical support for the connector modules 502 & 503. The different connector modules are then positioned on the frame assembly 501 to mate with the corresponding modules located in the base unit slots. In this embodiment the frame assembly is conductive around its perimeter and is then used to house optional conductive EMI shielding for when used with the optional Radio Frequency (RF) shield. Again this can either be a predetermined pattern or configured to suit specific user requirements. The types and positioning of the connector or contact modules are positioned to mate with the corresponding connector or contacts for that slot position on the base unit. Additionally for the modular interposer a prototyping area may be provided 505. This prototyping area may house the user loadboard(s) 507 onto which the Device or Module testing sites are provided (506). In this embodiment two connector types are illustrated, namely the Radio Frequency (RF) connector modules 502 which would normally be used for Radio Frequency (RF), microwave, high speed, or low noise signals. Also illustrated are the pogo pin contact modules 503 which would usually be used for digital, control, power, or lower speed Radio Frequency (RF) connections. The modular interposer unit also contains precision positioning mechanisms 504 which are used to accurately dock this unit to the base unit. Further the precision alignment mechanism(s) 404 may also be used for aligning an optional Radio Frequency (RF) shield.

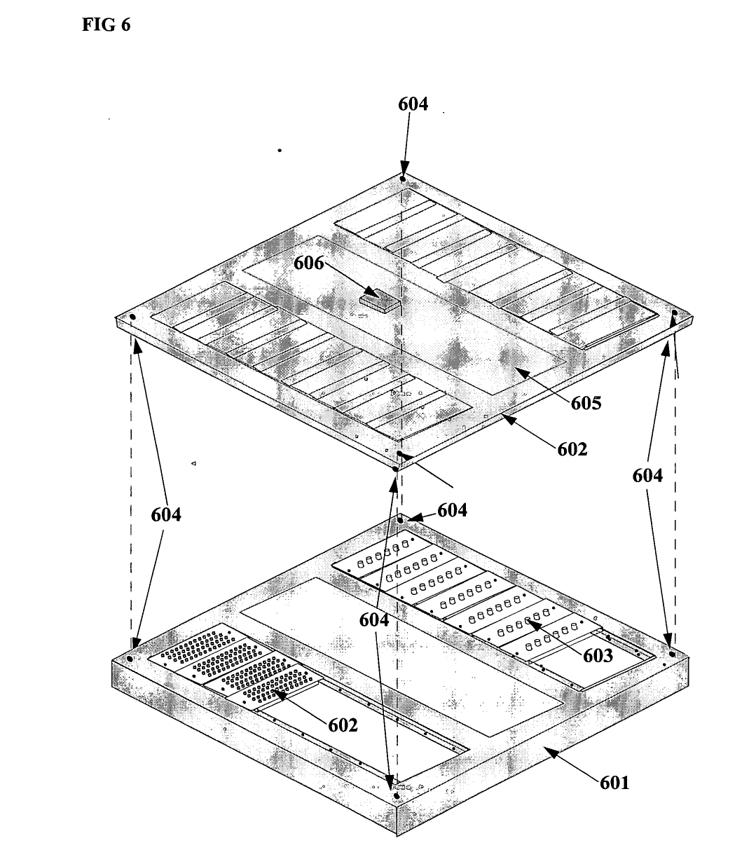

FIG. 6 is a perspective drawing showing one possible embodiment of the custom interposer Universal connectivity solution. The base unit 601 housing a selection of coaxial connectivity modules 603 and pogo pin connectivity modules 602 mates with a custom interposer assembly 602 which contains the corresponding mating contacts/sockets which are mounted on circuit board 605 with the Device or Module test site 606 also located on this board. Mechanical alignment is via alignment mechanism(s) 604.

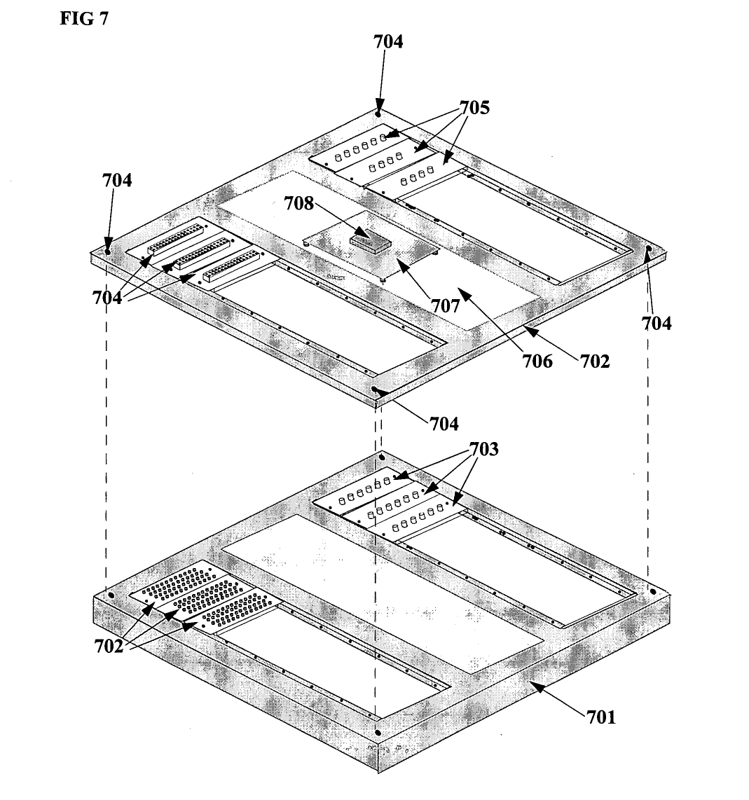

FIG. 7 is a perspective drawing showing one possible embodiment of the modular interposer Universal connectivity solution. The base unit 701 housing a selection of coaxial connectivity modules 703 and pogo pin connectivity modules 702 mates with a modular interposer assembly 702 which contains the corresponding mating contact modules 704 and coaxial modules 705. The modular interposer also may contain a prototyping are 706 onto which the users test board(s) 707 would be mounted. The device(s) or Module(s) Under Test 708 would then fit into the appropriate test sockets on the user test board(s) 707. Cables could then be used to connect between the interposer modules 704 & 705 and the users test board(s) 707.

FIG. 8 illustrates one possible embodiment of the Universal Connectivity Solution showing how the pogo pin mates with a custom interposer. On the right hand side is the base unit 801 showing pogo pin module 802 fitted containing a number of spring-loaded or elastomeric pogo pins 803. These are internally connected within the module to the user interface socket(s) 804 these could be any combination of VHDCI, SCSI, coaxial, header, D-Sub, or any commercially available or custom plug/socket type which can the interface with the users test equipment(s). On the left-hand side is the custom interposer board 805, for the custom solution all that is required are a series of contact areas 807 on the surface of the board which then mate with the pogo pins on the base unit module 803.

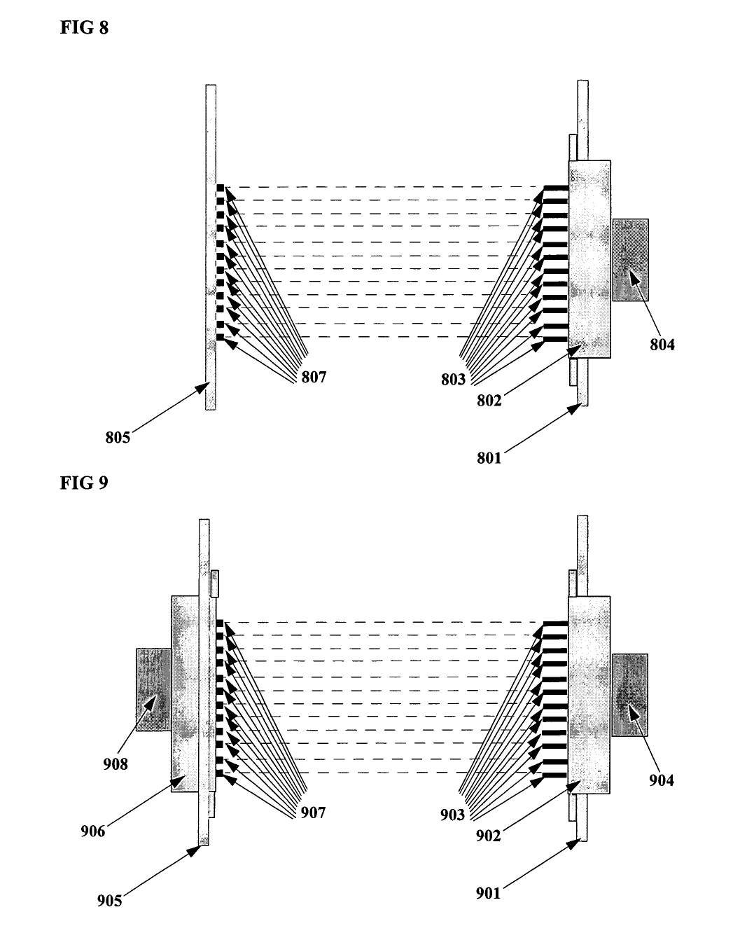

FIG. 9 illustrates one possible embodiment of the Universal Connectivity Solution showing how the pogo pin modular interconnect mates with a modular interposer. On the right hand side is the base unit 901 showing pogo pin module 902 fitted containing a number of spring-loaded or elastomeric pogo pins 903. These are internally connected within the module to the user interface socket(s) 904 these could be any combination of VHDCI, SCSI, coaxial, header, D-Sub, or any commercially available or custom plug/socket type which can the interface with the users test equipment(s). On the left-hand side is the modular interposer board 905, fitted to this board is a modular contact module 906 containing a series of mating contact areas 907 with are internally connected within the module to the user interface socket(s) 908, these could be any combination of VHDCI, SCSI, coaxial, header, D-Sub, or any commercially available or custom plug/socket type which can then interface with the user's device or module under test board. The contact is achieved by the series of contact areas 907 on the surface of the module which then mate with the pogo pins on the base unit module 903.

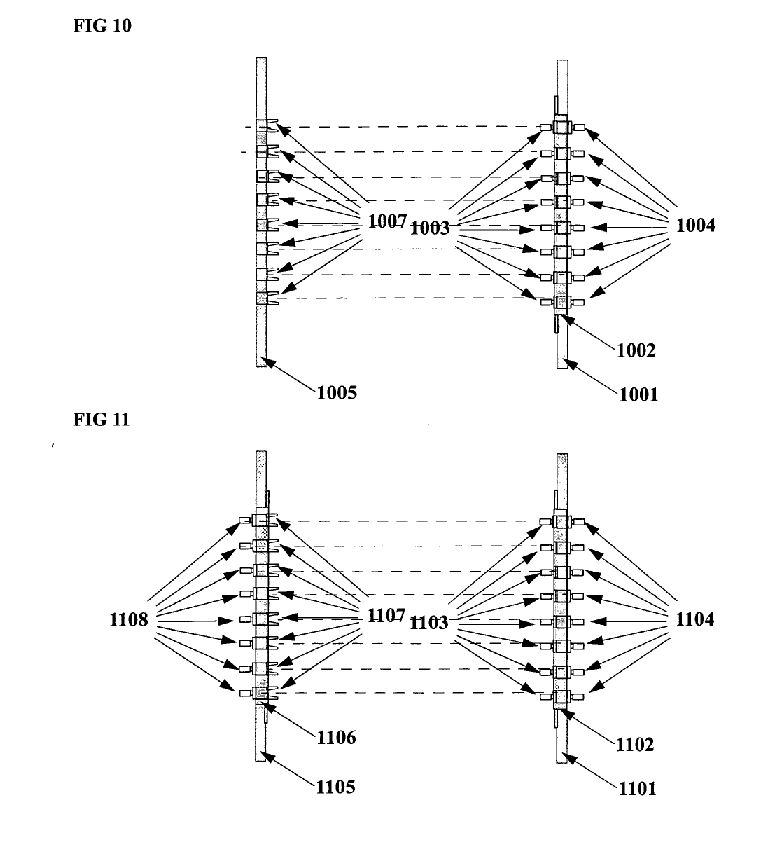

FIG. 10 illustrates one possible embodiment of the Universal Connectivity Solution showing how the coaxial modular interconnect mates with a custom interposer. On the right hand side is the base unit 1001 showing pogo pin module 1002 fitted containing a number of blind-mate coaxial plugs or sockets 1003. These are internally connected to a corresponding coaxial plug/socket or cable which can then interface with the users test equipment(s) and can be SMP, SMA, SMB, BNC, TNC or any other commercially available or custom plug/socket type. On the left-hand side is the custom interposer board 1005, for the custom solution all that is required are a series of integral blind-mate coaxial connectors 1007 on the surface of the board which then mate with the blind-mate coaxial connectors on the base unit module 1003.

FIG. 11 illustrates one possible embodiment of the Universal Connectivity Solution showing how the coaxial modular interconnect mates with a modular interposer. On the right hand side is the base unit 1101 showing pogo pin module 1102 fitted containing a number of blind-mate coaxial plugs or sockets 1103. These are internally connected to a corresponding coaxial plug/socket or cable which can then interface with the users test equipment(s) and can be SMP, SMA, SMB, BNC, TNC or any other commercially available or custom plug/socket type. On the left-hand side is the modular interposer board 1105, fitted to this board are the blind-mate coaxial connector modules which contain a series of integral blind-mate coaxial connectors 1107 on the surface of the board these can then mate with the blind-mate coaxial connectors on the base unit module 1103. The blind-mate coaxial connectors 1107 are also internally connected within the module to corresponding coaxial connector 1108 which can be SMP, SMA, SMB, BNC, TNC or any other commercially available or custom plug/socket type and is used to interface with the user's device or module under test board.

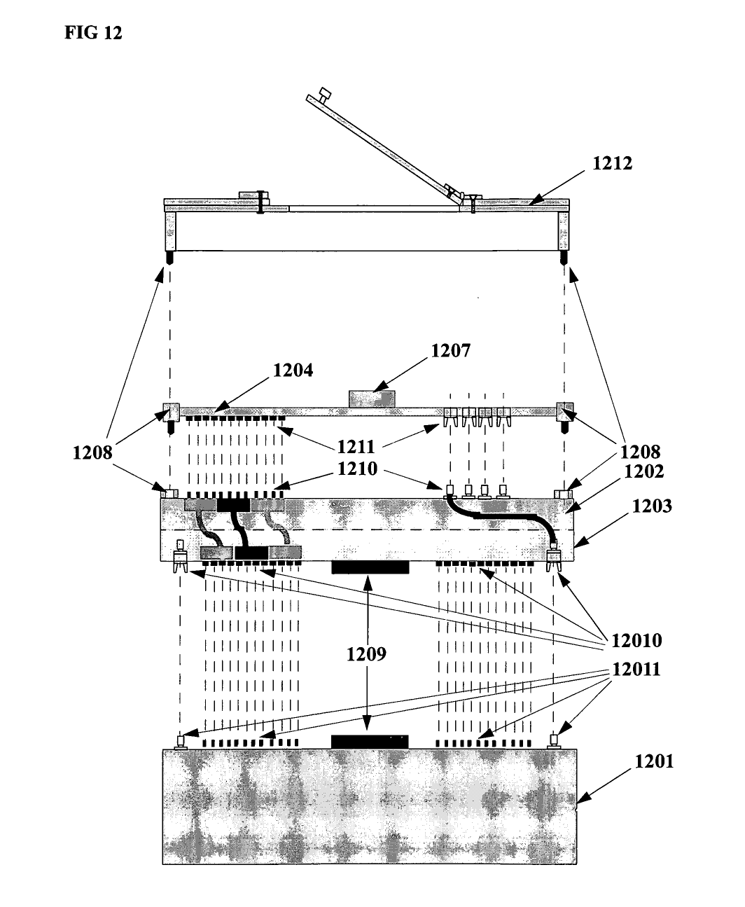

FIG. 12 illustrates one possible embodiment of the Universal Connectivity Solution showing how the base unit could be adapted to convert a third-party tester interface to the Universal Connectivity Solution format using a custom interposer board. The third party tester 1201 mates with a special adaptor plate 1203 which is then internally connected to the base unit 1202. The base unit 1202 then connects with the custom interposer 1204 onto which are located the Device or Module under test site(s). Onto this the optional Radio Frequency (RF) shield 1212 could then be fitted mechanically the tester 1201 would dock with the adaptor plate 1203 via the third party docking and alignment mechanism 1209. The adaptor plate 1203 is internally attached to the base unit 1202. The custom interposer is then attached and aligned via alignment mechanism 1208 and likewise to the optional Radio Frequency (RF) shield 1212 via mechanism 1208. Electrically the coaxial and pogo pin connectors etc. located on the third-party tester connect to mating contacts and coaxial connectors 1210 fitted to the adaptor plate 1203. These connectors are then internally connected to the modular connector modules 1210 located on the base unit 1202. This then connects to the corresponding connectors 1211 on the custom interposer 1204. If the third party tester supports Radio Frequency (RF) shielding then shielding contacts could be fitted to the adaptor plate, and throughout the universal solution by adding Radio Frequency (RF) shielding to the frames as described earlier.

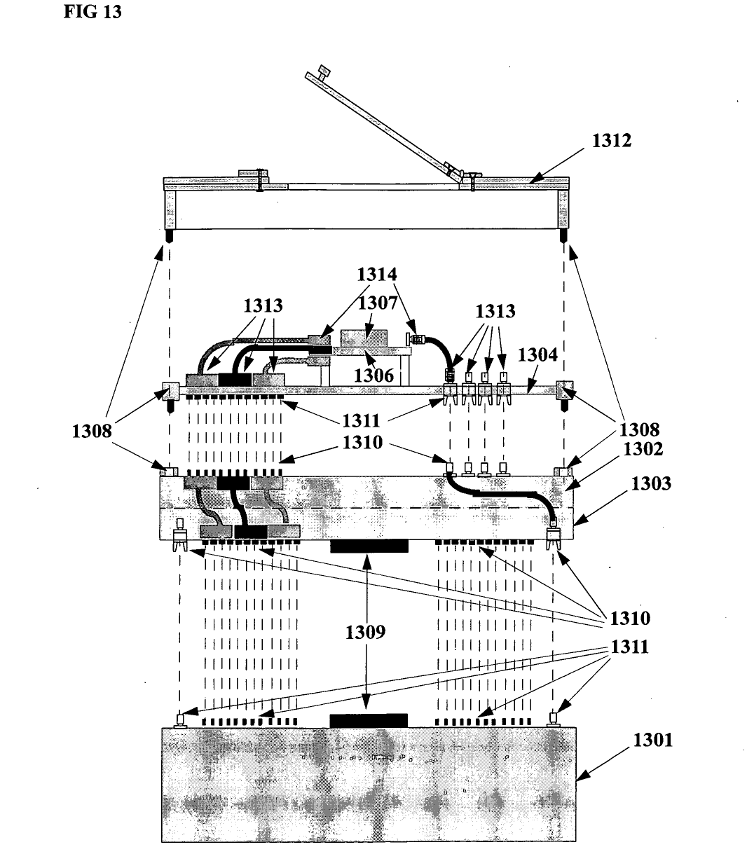

FIG. 13 illustrates one possible embodiment of the Universal Connectivity Solution showing how the base unit could be adapted to convert a third-party tester interface to the Universal Connectivity Solution format using a modular interposer board. The third party tester 1301 mates with a special adaptor plate 1303 which is then internally connected to the base unit 1302. The base unit 1302 then connects with the modular interposer 1304 onto which are located the Device or Module under test site(s). Onto this the optional Radio Frequency (RF) shield 1312 could then be fitted mechanically the tester 1301 would dock with the adaptor plate 1303 via the third party docking and alignment mechanism 1309. The adaptor plate 1303 is internally attached to the base unit 1302. The modular interposer is then attached and aligned via alignment mechanism 1308. The Users device or module test board(s) 1306 are then attached to the modular interposer 1304, with the Device or Module under Test site(s) 1307 fitted to this board. The optional Radio Frequency (RF) shield 1312 may then be attached to the interposer 1304 via mechanism 1308. Electrically the coaxial and pogo pin connectors etc. located on the third-party tester connect to mating contacts and coaxial connectors 1310 fitted to the adaptor plate 1303. These connectors are then internally connected to the modular connector modules 1310 located on the base unit 1302. This then connects to the corresponding connector modules 1311 on the modular interposer 1304. The corresponding connectors 1313 on the top side of the interposer modules may then be connected via cables to the required connectors 1314 on the user module or device test board 1306. If the third party tester supports Radio Frequency (RF) shielding then shielding contacts could be fitted to the adaptor plate, and throughout the universal solution by adding Radio Frequency (RF) shielding to the frames as described earlier.

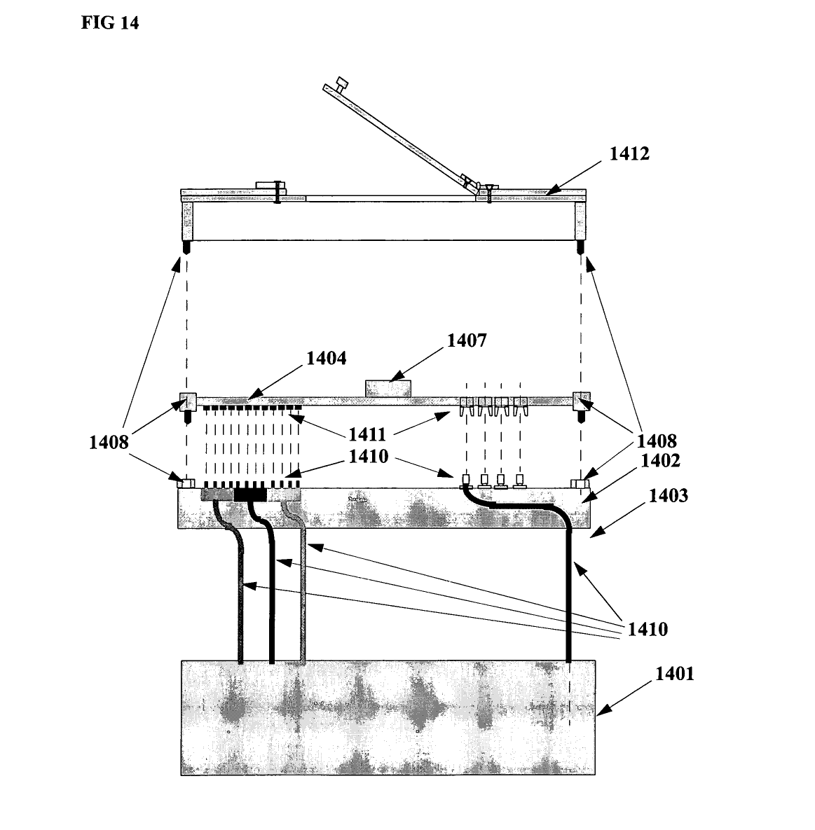

FIG. 14 illustrates one possible embodiment of the Universal Connectivity Solution using a custom interposer board.showing how the Universal Connectivity Solution would be connected to third-party test equipment(s). The third party test equipment(s) 1401 is connected to the base unit 1402 which then mates with the custom interposer 1404 onto which are located the Device or Module under test site(s). Onto this the optional Radio Frequency (RF) shield 1412 could then be fitted. Electrically the third-party test equipment(s) is connected to the base connect to the base unit 1402 via cables or optical fibers. The base unit then connects via connectors 1410 to the corresponding connectors 1411 on the custom interposer 1404. If the third party tester supports Radio Frequency (RF) shielding then shielding contacts could be fitted to the adaptor plate, and throughout the universal solution by adding Radio Frequency (RF) shielding to the frames as described earlier.

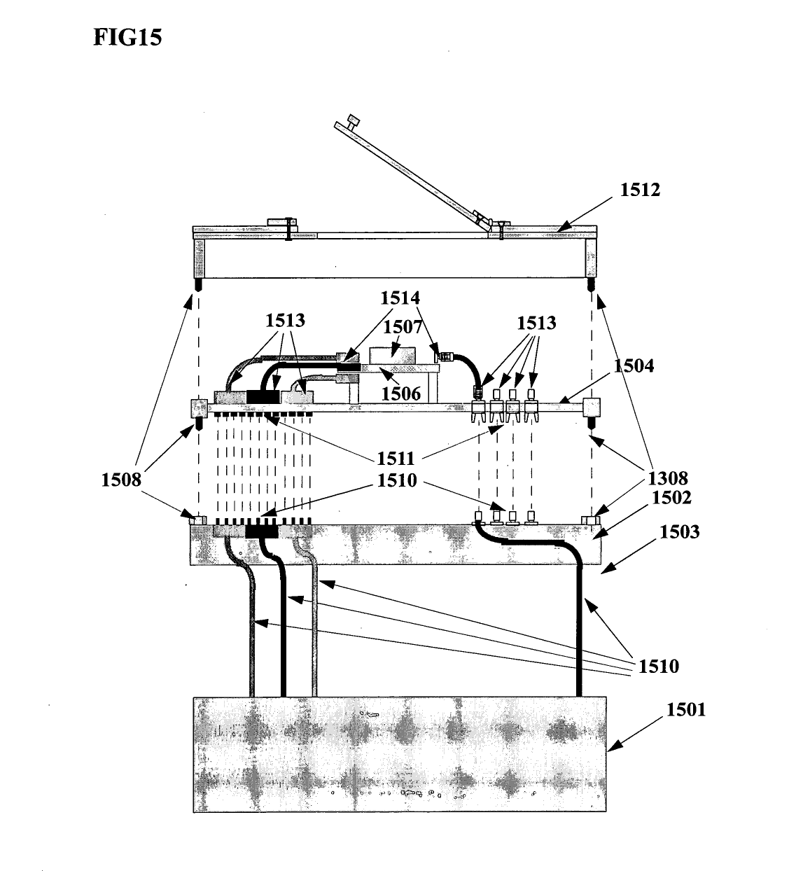

FIG. 15 illustrates one possible embodiment of the Universal Connectivity Solution using a modular interposer board.showing how the Universal Connectivity Solution would be connected to third-party test equipment(s). The third party test equipment(s) 1501 is connected to the base unit 1502 which then mates with the modular interposer 1504 onto which is fitted the user device or module test board(s) 1506 containing device or module test site(s) 1507. Onto this the optional Radio Frequency (RF) shield 1512 could then be fitted. Electrically the third-party test equipment(s) is connected to the base connect to the base unit 1502 via cables or optical fibers. The base unit then connects via base unit connector modules 1510 to the corresponding connector interposer connector modules 1511 on the interposer 1504. The corresponding connectors 1513 on the top side of the interposer modules may then be connected via cables to the required connectors 1514 on the user module or device test board 1306. If the third party tester supports Radio Frequency (RF) shielding then shielding contacts could be fitted to the adaptor plate, and throughout the universal solution by adding Radio Frequency (RF) shielding to the frames as described earlier.

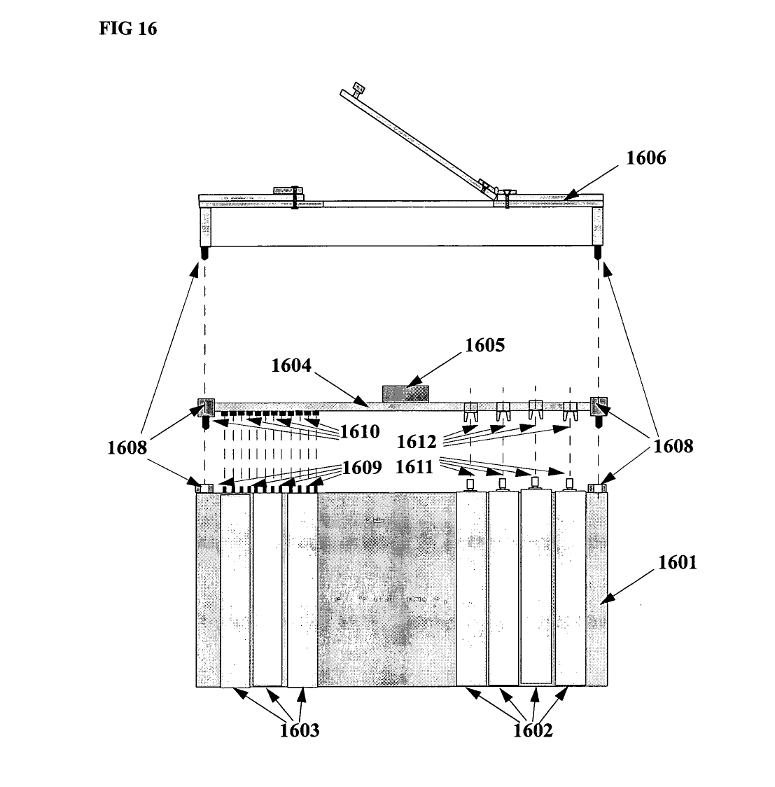

FIG. 16 illustrates one possible embodiment of the Universal Connectivity Solution using a custom interposer board.showing how the Universal Connectivity Solution would be connected to internally fitted modules or test equipment(s). The internally fitted modules or test equipment(s) 1602 and 1603 are located within the base unit 1601, this then mates with the custom interposer 1604 onto which are located the Device or Module tinder test site(s) 1605. Onto this the optional Radio Frequency (RF) shield 1606 could then be fitted, the alignment and docking is achieved via the precision alignment mechanism(s) 1608. Electrically the internal test equipment(s) connectors may replace the modular connectors that would normally be located on the base unit 1601. This example shows Radio Frequency (RF) or high-speed digital modules 1602 fitted with blind-mate coaxial connectors 1611, these connectors would then mate with the corresponding coaxial connectors 1612 fitted to the custom interposer board 1604. Also shown are analog, control, digital or lower-speed Radio Frequency (RF) type modules 1603 fitted with pogo-pin type connectors 1609, in this case the pogo pin connectors would mate with the corresponding contact areas 1610 on the custom interposer board 1604. If the third party tester supports Radio Frequency (RF) shielding then shielding contacts could be fitted to the adaptor plate, and throughout the universal solution by adding Radio Frequency (RF) shielding to the frames as described earlier.

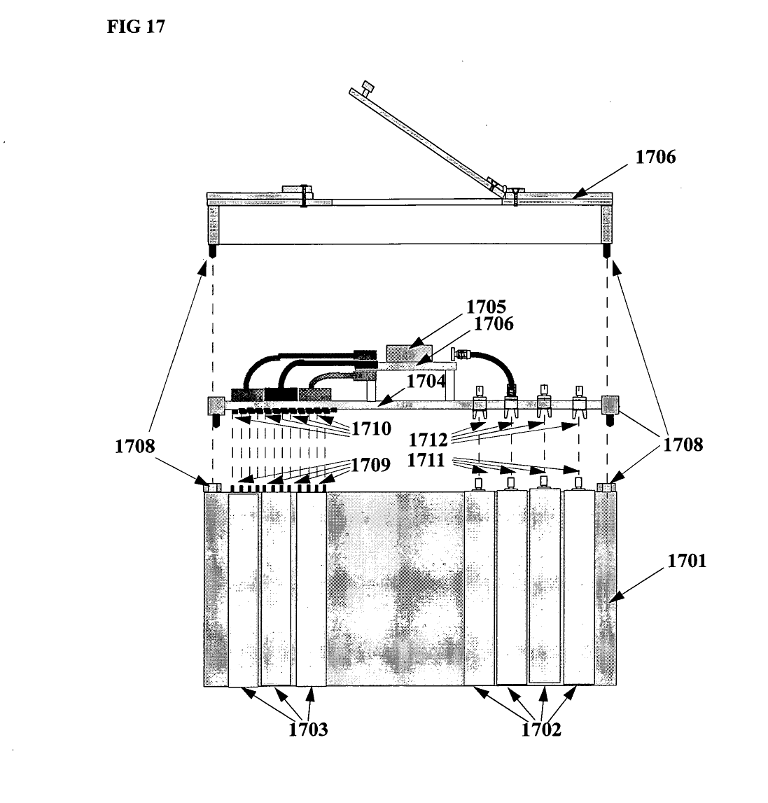

FIG. 17 illustrates one possible embodiment of the Universal Connectivity Solution using a modular interposer board.showing how the Universal Connectivity Solution would be connected to internally fitted modules or test equipment(s). The internally fitted modules or test equipment(s) 1702 and 1703 are located within the base unit 1701, this then mates with the modular interposer 1704 onto which are located the user test board(s) 1706 containing the Device or Module under test site(s) 1705. Onto this the optional Radio Frequency (RF) shield 1706 could then be fitted, the alignment and docking is achieved via the precision alignment mechanism(s) 1708. Electrically the internal test equipment(s) connectors may replace the modular connectors that would normally be located on the base unit 1701. This example shows Radio Frequency (RF) or high-speed digital modules 1702 fitted with blind-mate coaxial connectors 1711, these connectors would then mate with the corresponding coaxial connector modules 1712 fitted to the modular interposer board 1704, from here connection to the user test board can be made via coaxial cables. Also shown are analog, control, digital or lower-speed Radio Frequency (RF) type modules 1703 fitted with pogo-pin type connectors 1709, in this case the pogo pin connectors would mate with the corresponding contact areas 1710 on the modular interposer board 1704, in this case connection to the users test board(s) would be via suitable cables. If the third party tester supports Radio Frequency (RF) shielding then shielding contacts could be fitted to the adaptor plate, and throughout the universal solution by adding Radio Frequency (RF) shielding to the frames as described earlier.

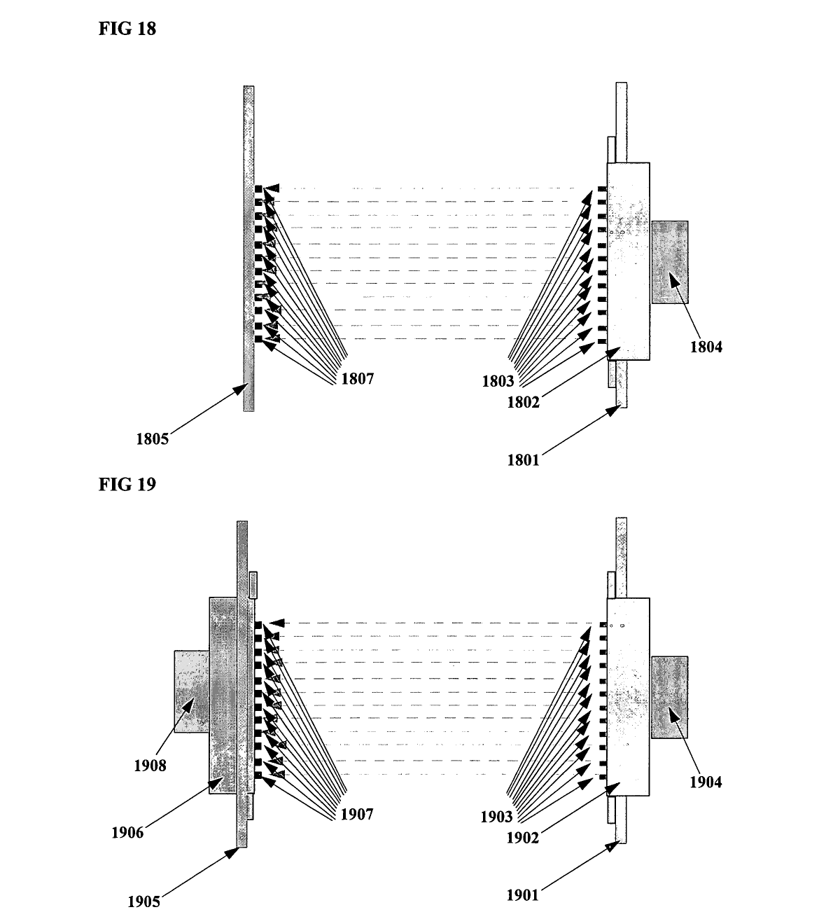

FIG. 18 illustrates one additional possible embodiment of the Universal Connectivity Solution module showing how the optical base unit module mates with a custom interposer. On the right hand side is the base unit 1801 showing optical module 1802 fitted containing a number of optical light-emitting optical sources 1803. These are internally connected within the module to the user interface socket(s) 1804 these could be any combination of VHDCI, SCSI, coaxial, header, D-Sub, or any commercially available or custom plug/socket type which can the interface with the users test equipment(s). On the left-hand side is the custom interposer board 1805, for the custom solution all that is required are a series of photodiodes 1807 on the surface of the board which then mate with the light emitting or laser on the base unit module 1803. Additionally this system could be used to test laser diodes, photodiodes, or photodetectors by making the modules able to accommodate the devices requiring test.

FIG. 19 illustrates one additional possible embodiment of the Universal Connectivity Solution module showing how the optical base unit module mates with a modular interposer. On the right hand side is the base unit 1901 showing optical module 1902 fitted containing a number of optical light-emitting optical sources 1903. These are internally connected within the module to the user interface socket(s) 1904 these could be any combination of VHDCI, SCSI, coaxial, header, D-Sub, or any commercially available or custom plug/socket type which can the interface with the users test equipment(s). On the left-hand side is the modular interposer board 1905, for the modular solution all that is required is a module containing a series of photodiode 1907 on the surface of the board which then mate with the light emitting or laser on the base unit module 1903. The signals detected by these diodes may then be fed via connectors and cabling to the user test board, amplified by the photodiode module first before routed to the test board or to the base unit. Additionally this system could be used to test laser diodes, photodiodes, or photodetectors by making the modules able to accommodate the devices requiring test.

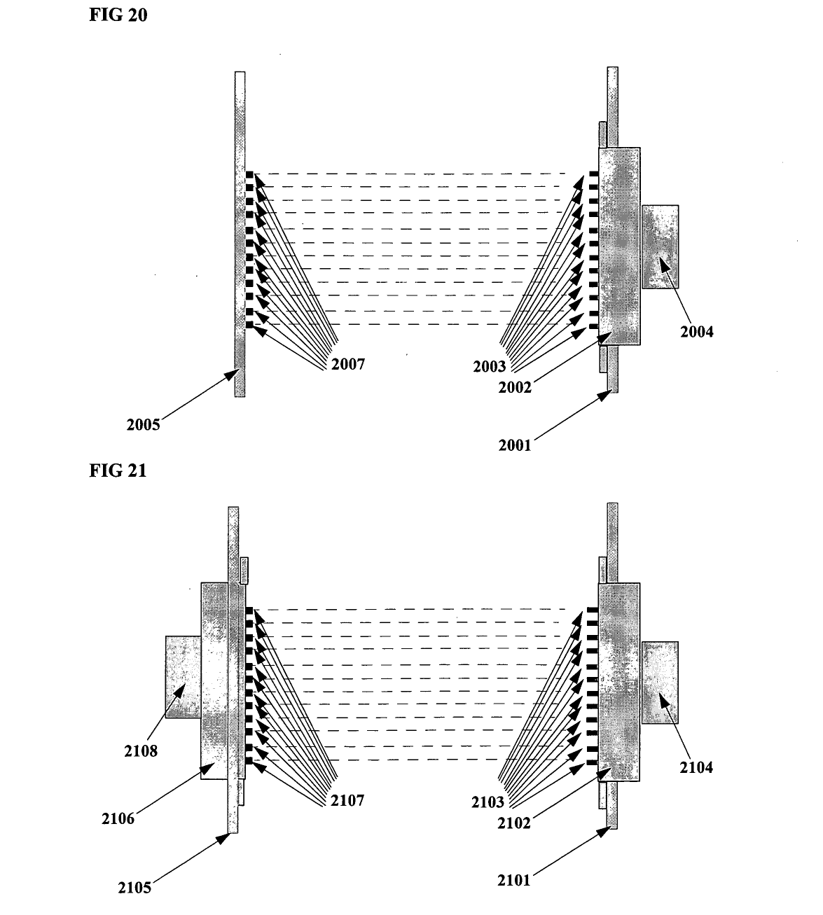

FIG. 20 illustrates one additional possible embodiment of the Universal Connectivity Solution module showing how the electromagnetic base unit module mates with a custom interposer. On the right hand side is the base unit 2001 showing electromagnetic module 2002 fitted containing a number of electromagnetic sources 2003. These are internally connected within the module to the user interface socket(s) 2004 these could be any combination of VHDCI, SCSI, coaxial, header, D-Sub, or any commercially available or custom plug/socket type which can the interface with the users test equipment(s). On the left-hand side is the custom interposer board 2005, for the custom solution all that is required are a series of electromagnetic sensors or reed relay contacts 2007 on the surface of the board which then couples with the electromagnetic sources on the base unit module 2003. Additionally this system could be used to test electromagnetic sources, detectors, or switches by making the modules able to accommodate the devices requiring test.

FIG. 21 illustrates one additional possible embodiment of the Universal Connectivity Solution module showing how the electromagnetic base unit module mates with a modular interposer. On the right hand side is the base unit 2101 showing an electromagnetic module 2102 fitted containing a number of electromagnetic sources 2103. These are internally connected within the module to the user interface socket(s) 2104 these could be any combination of VHDCI, SCSI, coaxial, header, D-Sub, or any commercially available or custom plug/socket type which can the interface with the users test equipment(s). On the left-hand side is the modular interposer board 2105, for the modular solution all that is required is a module containing a series of electromagnetic detectors or switches 2107 these then couple with the electromagnetic source(s) on the base unit module 2103. Additionally this system could be used to test electromagnetic sources, detectors, or switches by making the modules able to accommodate the devices requiring test.

1) A free-standing universal connectivity apparatus to connect between a semiconductor tester, or external test equipment(s), and a detachable interposer for the purpose of testing semicon ductor integrated circuits, hybrids or modules comprising:
(a) A Free standing base unit
(b) A quick-release Detachable interposer
(c) A precision alignment mechanism for docking between (a) and (b)
(d) Connectors for cabling to external test equipment(s) or semiconductor tester
(e) Test socket(s) for integrated circuit(s) or module(s) under test
(f) Circuit board or cabling to connect between interposer and test socket.

2) The Free standing connectivity apparatus of claim 1 wherein said base unit contains connectors located in modules.

3) The Free standing connectivity apparatus of claim 1 wherein the base unit contains connectors which are attached directly to unit.

4) The Free standing connectivity apparatus of claim 1 wherein the base unit connectors are part of internally-mounted test equipment(s) or modules.

5) The Free standing connectivity apparatus of claim 1 wherein the Interposer unit of claim 1 has connectors which are located in modules.

6) The Free standing connectivity apparatus of claim 1 where the Interposer unit contains area for attachment of user test board(s) or module(s)

7) The Free standing connectivity apparatus of claim 1 wherein the connectors are attached directly to the Interposer Unit.

8) The Free standing connectivity apparatus of claim 1 where a quick-release detachable Radio Frequency (RF) shield is fitted.

9) The Free standing connectivity apparatus of claim 1 where the interposer or base unit of claim 1 is used for testing opto-electronic devices

10) The Free standing connectivity apparatus of claim 1 where the interposer or base unit is used for testing electromagnetic devices

11) The Free standing connectivity apparatus of claim 1 precision alignment mechanism when used as a part of this apparatus.

12) The Free standing connectivity apparatus of claim 1 where a circuit board or a module is fitted within said apparatus to provide increased functionality

13) The Free standing connectivity apparatus of claim 1 where the apparatus is connected to both a semiconductor tester and external equipment(s) thereby increasing the test capability.

14) The Free standing connectivity apparatus of claim 1 where the apparatus is connected to both a semiconductor tester and internal equipment(s) thereby increasing the test capability.

15) The Free standing connectivity apparatus of claim 1 where the apparatus is connected to both internal test equipment(s) and external equipment(s) thereby increasing the test capability.

16) The Free standing connectivity apparatus of claim 1 where the apparatus is connected to a semiconductor tester, external equipment(s) and internal test equpment(s) thereby increasing the test capability.

2) The portable low-cost detachable RF shield apparatus for the purpose of providing instant shielding for circuit boards, modules or devices, comprising:
